(19) United States
(12) Patent Application Publication
(10) Pub. No.: US 2009/0219702 A1
(43) Pub. Date: Sep. 3, 2009

(54) Electronic Circuit Plug-In Module for a Mounting Rack

(75) Inventors: Paul Mazura, Karlsbad (DE); Uwe Rieger, Karlsbad (DE); Michael Joist, Gaggenau (DE)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: Schroff GmbH, Straubenhardt (DE)

(21) Appl. No.: 12/396,729

(22) Filed: Mar. 3, 2009

(30) Foreign Application Priority Data
Mar. 3, 2008 (EP) EP08152211.2

(51) Int. Cl. H05K 1/14

(52) U.S. Cl. 361/740

(57) ABSTRACT

An electronic plug-in module to be accommodated in a mounting rack with a module rail in the front region comprises a circuit board, a circuit board holder and an adapter. The adapter features a receptacle for a mounting element in order to mount the adapter on the module rail. The circuit board holder is fixed on the circuit board in the front corner region of the circuit board. It features a coupling structure that is coupled to a corresponding coupling element of the adapter in order to produce a coupling between the circuit board holder and the adapter. In an end position of the plug-in module in the mounting rack, the adapter and the circuit board holder cooperate in such a way that the plug-in module is held in its position in the mounting rack.

### TECHNICAL FIELD OF THE INVENTION

The present invention pertains to an electronic plug-in module to be accommodated in a mounting rack with a module rail in the front region, comprising a circuit board, a circuit board holder and an adapter.

### BACKGROUND OF THE INVENTION

Modularly designed electronic devices feature a mounting rack, into which individual modules in the form of plug-in modules can be inserted. On their rear side, the plug-in modules feature a multicontact plug that is inserted into a plug connector (plug receptacle) on the “backplane” of the mounting rack. The plug of the plug-in module may either consist of an integrated plug, e.g., a connector strip, a connector tab or a “card-edge-connector,” or of a separate connector strip that is fixed on the plug-in module.

In order to hold the plug-in modules in their positions within the mounting rack, they are fixed by means of suitable locking elements. Conventional locking devices that prevent an unintentional detachment of the modules consist of screws or quick-acting closures. In this case, it is common practice to either use a lever or lever pull handle that is fixed on the circuit board and cooperates with a front module rail of the mounting rack or to screw a front plate of the plug-in module to the module rail by means of a screw. For this purpose, the plug-in module is pushed into the mounting rack until the front plate tightly contacts the module rail of the mounting rack. The module rail of the mounting rack consists of a transversely extending profiled rail, to the lateral surfaces of which the lateral parts of the mounting rack can be fixed. The module rail features a front side with a locating face that is suitable for positioning and fixing a front plate of a plug-in module thereon. The front side of the module rail contains a plurality of bores, into which screws or mounting elements can extend in order to fix the front plates on the mounting rack. Alternatively, the front side of the module rail may also feature a transversely extending groove, into which a perforated rail with (threaded) bores can be inserted. Consequently, a module rail always provides the option of fixing a front plate thereon.

In modern telecommunications systems, plug-in modules are developed in accordance with the AMC standard (Advanced Mezzanine Card) that is defined by the PICMG (PCI Industrial Computer Manufacturers Group). Modules according to this specification are relatively small in comparison with known 19-modules and have a comparatively shorter front plate that does not protrude over the circuit board of the plug-in module with respect to its height. The front plate may be pre-installed on the circuit board of the plug-in module. It usually has a U-shaped cross section. The plug of the AMC plug-in module is integrated into the circuit board on its rear end in the form of a connector tab (card-edge-connector).

Due to their standardized dimensions and permissible tolerances, AMC plug-in modules do not feature conventional mounting flanges on the front plate because the plug-in modules should also be inserted into so-called carriers (adapters) that do not feature a corresponding mounting plane or mounting rail (module rail) on the mounting rack. The depth stop of the modules (in the inserting direction) within the carrier is realized with the rearmost edge of the circuit board. The depth stop is required for reliably contacting the individual contact rows of the connector tab to the plug connector (plug receptacle) of the carrier. A specially standardized locking mechanism of these modules (card-edge-systems) secures their end position. Due to the stricter requirements with respect to the shock and vibration resistance of the systems, however, conventional mounting options are reaching their limitations.

Due to the standardized and permitted tolerances of the individual components of AMC systems, particularly the plug-in modules and mounting racks, it is not easy to provide mounting flanges on the front plate that contact a mounting rail of the mounting rack and simultaneously ensure the contact of the plug-in module with the mounting rack in this fashion. For example, if the front plate were tightly screwed onto the mounting rack, an excessively high pressure could possibly be exerted upon the integrated plug of the plug-in module or the connector housing of the plug connector such that the circuit board or the connector tab of the plug-in module could be damaged or destroyed.

### SUMMARY

An exemplary embodiment of a plug-in module to be accommodated in a mounting rack with a rail in the front region comprises a circuit board, a circuit board holder and an adapter. The circuit board holder is fixed on the circuit board in the front corner region thereof. It comprises a coupling structure that is coupled to a corresponding coupling element of the adapter in order to produce a coupling between the circuit board holder and the adapter. The adapter, which is preferably angled, also features a receptacle for a mounting element in order to mount the adapter on the module rail of the mounting rack. The plug-in module is fixed to the mounting rack by the connection between the adapter and the mounting rack, as well as the coupling between the adapter and the circuit board holder. Once the plug-in module is completely inserted into the mounting rack and situated in an end position, the adapter and the circuit board holder cooperate in such a way that the plug-in module is held in its position in the mounting rack.

The adapter and the circuit board holder can provide the advantage that it is not dependent on a front plate of the plug-in module. It is furthermore possible, in particular, to retrofit plug-in modules with front plates that do not feature mounting flanges to the mounting device in order to install and mount the front plate and therefore the plug-in module with the front plate fixed thereon in the mounting rack. The mounting device can also be used with plug-in modules that do not feature a front plate.

In a new standardized development of the PICMG, AMC plug-in modules are specified that are intended for future use in “ruggedized MTCA” mounting racks with a mounting rail in their front region. Such mounting racks and AMC plug-in modules are adapted to the new stricter requirements with respect to shocks and vibrational stresses. AMC modules used so far that feature a shorter front plate without mounting flanges need to be modified for use in the “ruggedized MTCA” mounting rack. This is realized by replacing the front plates of the modules because the front plates used so far do not provide a front mounting. Thusly modified front plates with mounting flanges can then be fixed on the mounting rail as described in commonly owned, co-pending U.S. application Ser. No. 12/350,025, filed Jan. 7, 2009.

A mounting device such as described above also can provide the advantage that “normal” AMC modules can also be retrofitted for MicroTCA mounting racks. Plug-in modules according to the currently valid “AMC.0 Standard” that feature the shorter front plate without mounting flanges can also be used.

Due to the utilization of the inventive mounting device, it is possible to forgo the (expensive) replacement of the (partially individualized) front plate in order to mount the plug-in module in the mounting rack in a robust, strong and reliable fashion. The auxiliary adapter makes it possible to continue using the existing front plates. Consequently, retrofitting is much more cost-efficient than replacing the existing front plate with a modified (extended) front plate. The same front plates therefore can be used for all AMC modules and inexpensively produced in large quantities.

The cooperation between the adapter and the circuit board holder is particularly suitable for plug-in modules, the circuit board of which comprises an integrated connector (card-edge-connector). In circuit boards of this type, it is particularly important that the forces exerted by a mounting device for installing and mounting the plug-in module are not transmitted to the circuit board or the end of the connector tab in an uncontrolled fashion, but rather controlled. Otherwise, the circuit board may be damaged.

This aspect is taken into consideration in an exemplary embodiment by means of the mounting device with the coupling between the circuit board holder and the adapter that allows a relative movement between the two elements. This relative movement is also possible when the adapter of the mounting device is mounted or fixed on the module rail of the mounting rack. In one preferred embodiment, a relative movement between the adapter and the circuit board holder can be realized (during the coupling of the two elements) in such a way that the plug-in module can be moved in the mounting rack (preferably only) in the inserting direction as long as it hasn't reached the end position in the inserted state. The mounting device (consisting of the adaptor and the circuit board holder), particularly the coupling between the circuit board holder and the adapter, allows a relative movement between the two components such that the force transmitted to the circuit board of the plug-in module can be limited.

The relative movement provides the option of initially mounting the adapter on the module rail of the mounting rack, e.g., by means of screws, and to subsequently insert the plug-in module into the mounting rack until the circuit board holder engages with the adapter. Due to the special type of coupling, a plug-in module can be additionally displaced in the inserting direction, namely also after the engagement between the adapter and the circuit board holder, such that the plug-in module can be manually pushed into its end position. After the end position is reached, the two components can no longer be moved relative to one another because the circuit board holder cannot be moved opposite to the inserting direction due to the coupling (and a movement in the inserting direction is not possible in the end position). The plug-in module is reliably held in its position in the mounting rack. Stricter requirements with respect to vibration or shock resistance can also be fulfilled with this embodiment.

Since the connector tab of the circuit board is manually pressed into the plug receptacle on the backplane of the mounting rack, the force to be exerted can be easily controlled. The circuit board is not subjected to excessive forces generated by screws or levers.

Another advantage of such a plug-in module can be seen in that the conductive contact between the plug-in module and the mounting rack is produced by means of the preferably metallic adapter and the circuit board holder that preferably is also conductive. The (electromagnetic) shielding of the mounting rack is simultaneously improved with this measure.

In one preferred embodiment of the plug-in module, the mounting device is designed in such a way that the coupling structure of the circuit board holder consists of a retaining structure and the corresponding coupling element of the adapter consists of a catch element. The coupling between the circuit board holder and the adapter is produced by means of a snap-in connection. The coupling structure and the coupling element consist of two corresponding components, e.g., two catches that can engage into one another. The snap-in connection preferably allows several positions between the two catches in this case. This also allows a relative movement between the adapter and the circuit board holder. The coupling elements may consist, for example, of hooks, tabs or springable elements that engage on a rack rail of sorts that serves as the coupling structure. The catch element preferably engages into a front rack rail referred to the inserting direction during the insertion of the plug-in module, i.e., into a rack rail that is situated as far as possible from the front side of the circuit board. The catch element of the adapter is only snapped into a rack rail near the front side shortly before the end position is reached.

Alternatively, the coupling element may consist of a receptacle and the coupling structure may consist of a ratcheting catch that engages in the receptacle.

### BRIEF DESCRIPTION OF THE DRAWINGS

One preferred embodiment of a plug-in module is described in greater detail below with reference to the drawings. The characteristics illustrated therein can be used individually or in combination in order to realize preferred embodiments of the invention. They do not restrict the generality of the invention in any way. In these drawings:

FIG. 1 shows a mounting rack with two plug-in modules;

FIG. 2 shows an inventive plug-in module with adapter and circuit board holder;

FIG. 3 shows a schematic section through a mounting rack with the plug-in module according to FIG. 2;

FIG. 4 shows a schematic representation of an embodiment of a plug-in module;

FIGS. 5a-c show another embodiment of a plug-in module, and

FIGS. 6a-c show a detailed section through the plug-in module according to FIG. 5 in a mounting rack.

### DETAILED DESCRIPTION OF EXEMPLARY EMBODIMENTS

In the following description, like numbers refer to like elements.

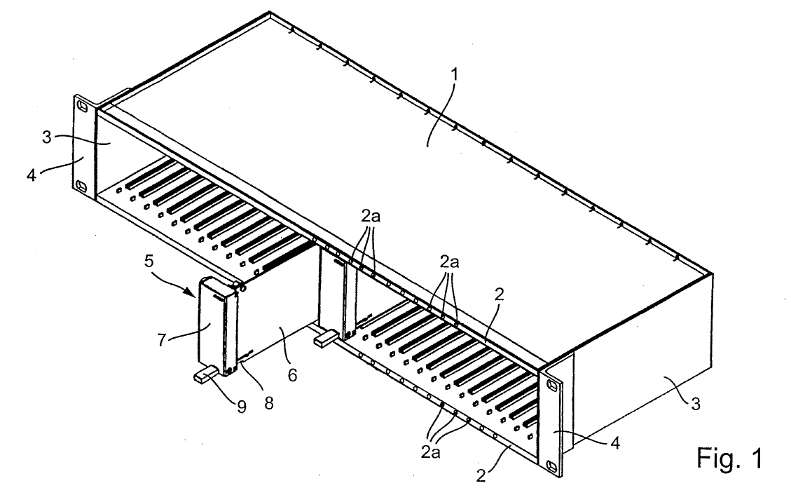

FIG. 1 shows a mounting rack 1 that is realized in the form of a MicroTCA mounting rack (Micro Telecommunications Computing Architecture). Two module rails 2 arranged in the front region of the mounting rack 1 extend between the two sidewalls 3 that each feature a mounting flange 4 in order to mount the mounting rack 1 in a switchgear cabinet.

The module rails 2 each feature a perforated rail that is directed toward the front side of the module rack 1 and contains several bores 2a, into which mounting screws can be screwed in order to mount the plug-in modules. The perforated rail may also be realized in the form of a groove, into which clamping elements can be screwed with the aid of screws, for example, in clamping nuts arranged in the groove.

Several plug-in modules 5 that comprise a circuit board 6 and a front plate 7 can be accommodated in the mounting rack 1, wherein the front plate 7 is screwed to the circuit board 6 by means of a (not-shown) circuit board holder. In order to mount the plug-in module 5 in the form of an AMC module within the mounting rack 1, a locking mechanism 8 is provided that is actuated by means of a locking lever 9. The locking lever 9 also optionally actuates a switch on the circuit board 6.

The plug-in module 5 is held in the mounting rack 1 by the locking mechanism 8 only. The front plate 7 shown does not feature any mounting flanges so it cannot be screwed to the module rail 2, and stricter requirements with respect to vibrations cannot be fulfilled.

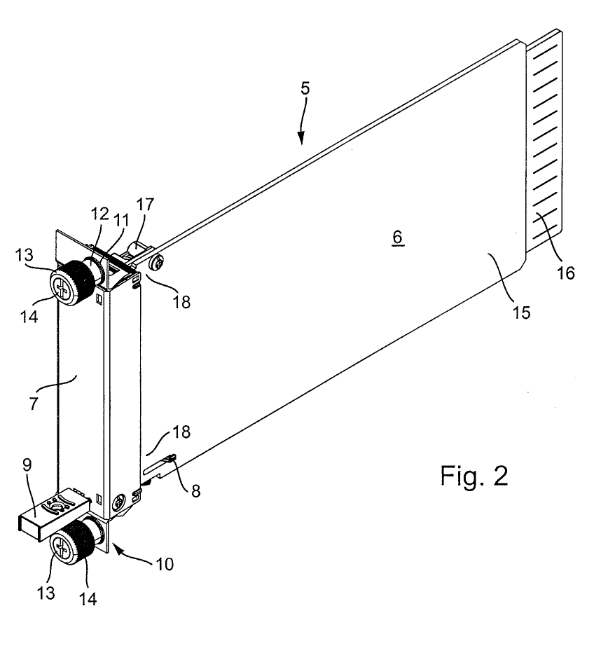

In order to improve the mounting of the plug-in module 5 in the mounting rack 1 and to utilize the mounting options provided by the module rail 2, it is either necessary to exchange the front plate 7 or to retrofit the plug-in module 5 with an adapter 10 as shown in FIG. 2.

An inventive plug-in module 5 according to FIG. 2 features a circuit board 6 and a front plate 7. Angled adapters 10, each with a receptacle 12 in the form of an opening 11 that serves for receiving a mounting element 13, are respectively arranged above and below the front plate 7. The mounting element 13 consists of a screw 14 that can be screwed into one of the bores 2a of the module rail 2 in order to reliably mount the plug-in module 5 in the mounting rack 1.

On its rear end 15, the circuit board 6 features an integrated plug in the form of a connector tab 16 as is typically used, e.g., on AMC modules.

The adapter 10 is coupled to a circuit board holder 17 such that the adapter 10 can be moved relative to the circuit board holder 17 in the longitudinal direction of the circuit board 6. The circuit board holder 17 is screwed on in the front corner region 18 of the circuit board 6 and holds the front plate 7 of U-shaped cross section, the U-limbs of which extend in the inserting direction.

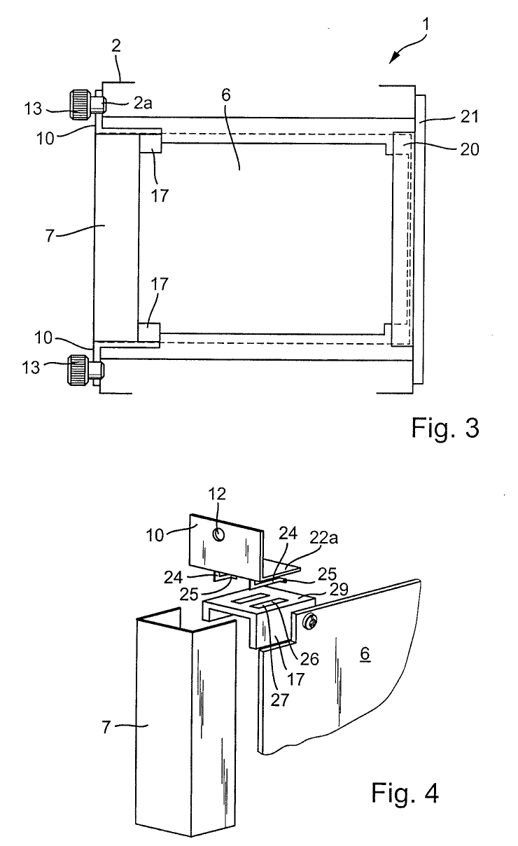

FIG. 3 shows a schematic section through a mounting rack 1, in which a plug-in module 5 is arranged in its functional position. The functional position is the end position of the plug-in module 5 referred to the inserting direction when the plug-in module 5 is inserted into the mounting rack 1 and the connector tab 16 of the circuit board 6 is completely inserted into a plug connector 20 (plug receptacle) on a backplane 21 of the mounting rack 1. The upper and lower adapters 10 are respectively coupled to the upper and the lower circuit board holder 17 of the plug-in module 5. The adapter 10 is simultaneously mounted on the module rail 2. Since the coupling between the adapter 10 and the circuit board holder 17 does not allow a movement of the circuit board holder 17 relative to the adapter 10 opposite to the inserting direction, the plug-in module 5 is fixed in its end position in the mounting rack 1.

FIG. 3 clearly shows that the AMC module 5 still contains the original face plate 7, the vertical dimension of which preferably corresponds to the height of the circuit board 6. The circuit board 6 may nominally also be slightly smaller, e.g., 0.3 mm smaller than the front plate 7.

According to FIGS. 3-6, the adapter is preferably angled and forms an L in a longitudinal section. The L-limb 22a of the L-shaped adapter 10 that extends in the longitudinal direction of the circuit board 6 features a coupling element 23.

In one preferred embodiment, the coupling between the circuit board holder 17 and the adapter 10 is produced by means of a snap-in connection. The coupling element 23 according to FIG. 4 is formed by two skid-like coupling plates 24 that extend in the inserting direction and preferably feature several hooks 25 that also extend in the longitudinal direction of the circuit board 6. The coupling plates 24 are arranged on the outside of the L-limb 22a.

The circuit board holder 17 is realized in a metallic fashion and usually consists of solid material, for example, of a die-cast part. In the embodiment according to FIG. 4, the circuit board holder 17 is realized in a U-shaped fashion, wherein the U-base features a coupling structure 26. The coupling structure 26 corresponds to the coupling element 23.

FIGS. 4-6 also show that the coupling structure 26 preferably forms an integral part of the circuit board holder 17. Analogously, the coupling element 23 preferably is integrally molded onto the adapter 10.

The coupling structure 26 is formed by two recesses 27 that extend in the longitudinal direction and preferably feature (not-shown) hooks that correspond to the hooks 25 of the coupling plates 24. In this case, the coupling plates 24 are smaller in their longitudinal direction than the recesses 27 so that the coupling plates 24 can be moved in the recesses 27. This allows a relative movement between the adapter 10 and the circuit board holder 17, wherein the hooks 25 only allow a movement of the circuit board holder 17 in the inserting direction relative to the adapter 10. A relative movement opposite to the inserting direction is prevented by the hooks.

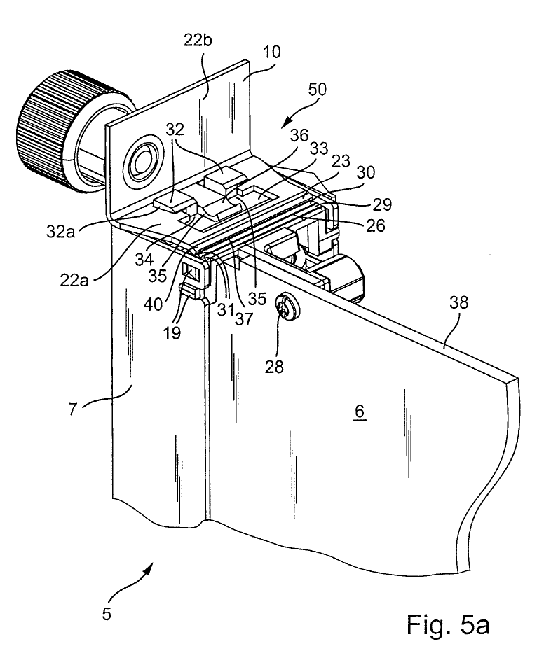

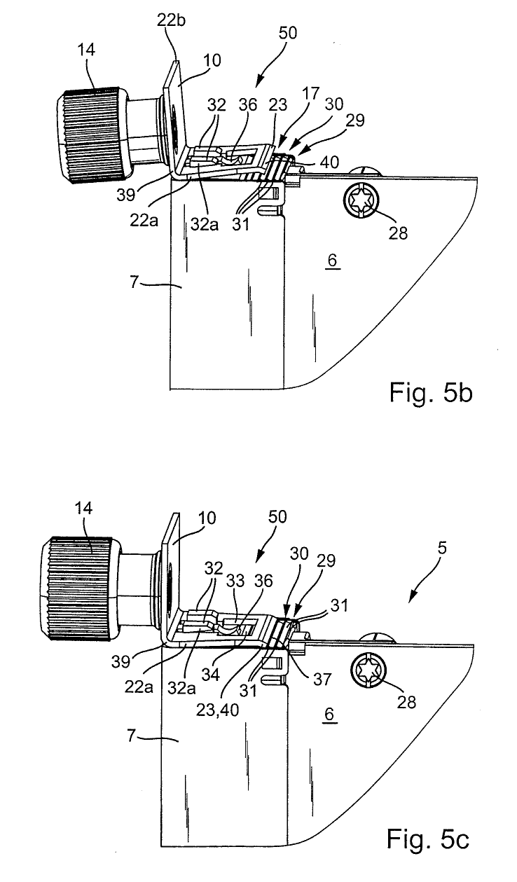

FIGS. 5a-c show detailed representations of the upper corner region of a plug-in module 5 with a mounting device 50 that consists of the adapter 10 and the circuit board holder 17.

The circuit board 6 is screwed to the circuit board holder 17 by means of a holding screw 28. A front plate 7 of U-shaped cross section is held on the circuit board holder 17 by means of a clamping connection. The width (dimension transverse to the inserting direction) of the circuit board holder 17 corresponds to the clear width between the two U-limbs of the front plate 7. The clamping connection is reinforced by means of a form-fitting connection of two holding tabs 19 of the circuit board 16 that are clipped into corresponding openings in the U-limbs of the front plate 7. The circuit board holder 17 and the front plate 7 may also be screwed to one another. However, it would also be conceivable to realize the circuit board holder 17 and the front plate in one piece, e.g., in the form of a die-cast part.

On its upper side 29, the circuit board holder 17 features an (integrated) coupling structure 26 that corresponds to a coupling element 23 of the adapter 10. The term “upper side” of the circuit board holder 17 refers to the outer side that extends horizontally and faces away from the circuit board 6. The upper side 29 is preferably aligned with the long narrow edge 38 of the circuit board 6.

The coupling structure 26 of the upper side 29 is formed by a (fine) toothing 30 with a plurality of adjacently arranged teeth 31 that are inclined toward the front plate 7. The maximum distance between two adjacent teeth 31 preferably is 1 mm, particularly no more than 0.5 mm. It is particularly preferred to use a toothing 30 in which the maximum distance between two adjacent teeth 31 is 0.2 mm, particularly no more than 0.1 mm. Each individual tooth 31 preferably extends over the entire width of the circuit board holder 17 such that it respectively forms a retaining rail.

Two guide tabs 32 of L-shaped cross section are also arranged on the upper side 29 of the circuit board holder 17, wherein the horizontal L-limb (transverse section 32a) extends parallel to the upper side 29. The two guide tabs 32 correspond to a guide receptacle 33 of the adapter 10, wherein the guide receptacle 33 features a widened first guide section 34 and a narrowed second guide section 35 that is directed toward the L-limb 22b of the adapter 10. The first guide section 34 of the guide receptacle 33 is realized in such a way that the guide tabs 32 of the circuit board holder 17 fit through the section. The second guide section 35 is realized in such a way that the guide tabs 32 can be displaced therein, but lifting off (in the vertical direction) of the adapter is prevented. Due to these measures, the adapter 10 can be movably coupled to the circuit board holder 17 and still displaced within predetermined limits. On the free end of the L-limb 22a, the adapter 10 features a coupling element 23 that is realized in the form of a catch element 40. The edge 37 of catch element 40 engages in the toothing 30 such that an arrangement of engaged teeth is produced. Due to the inclination of the teeth, an incremental movement is only possible in one direction, namely such that the adapter 10 can be moved relative to the circuit board holder in the direction of the front plate 7.

An elastically springable guide tab 36 is arranged between the two second guide sections 35 of the adapter and also separates the two first guide sections 34. The guide tab 36 exerts a force upon the adapter 10 such that the adapter 10 is tilted toward the front side of the circuit board 6 as shown in FIG. 5b. This allows a non-engaged displacement of the adapter 10 relative to the circuit board holder 17. The upper transverse sections 32a of the guide tabs 32 are inclined accordingly such that the horizontal L-limb 22a of the adapter 10 can also be pivoted upward, wherein the pivoting point consists of the (rounded) angle point 39 of the adapter 10.

FIG. 5c shows the mounting device 50 consisting of the adapter 10 and the circuit board holder 17 once the spring tab 36 is overcome by a force acting upon the adapter and the L-limb 22a is aligned parallel to the upper side 29. In this engaged position, the toothed edge 37 of the catch element 40 that is arranged on the front end of the adapter 10 and is slightly angled downward cooperates with the toothing 30 such that the adapter 10 and the circuit board holder 17 can only be moved relative to one another in one direction. The inclined teeth 31 limit the relative movement such that the circuit board holder 17 and therefore the plug-in module can be moved relative to the adapter 10 in the inserting direction. A relative movement opposite to the inserting direction is prevented.

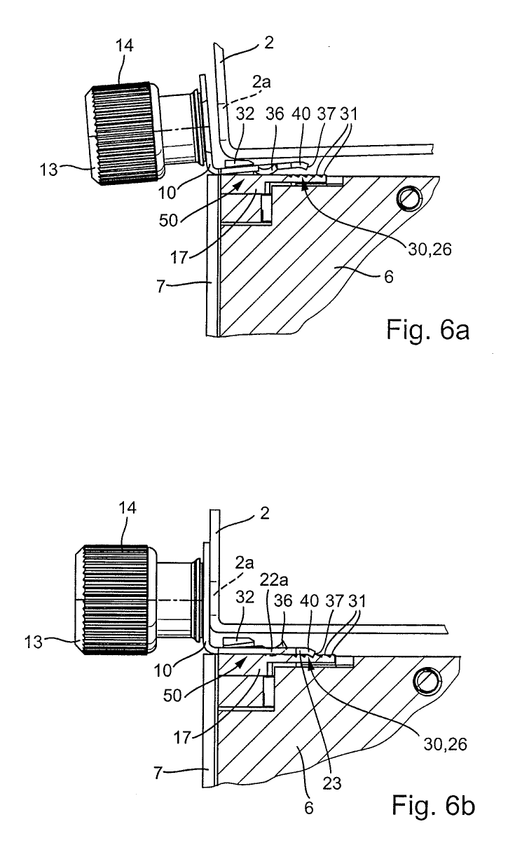

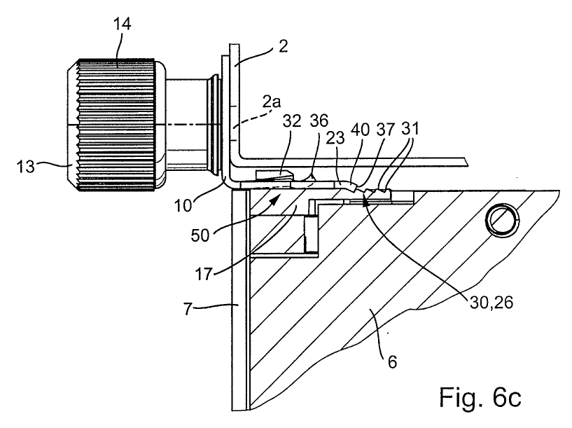

FIGS. 6a-c show the plug-in module 5 according to FIGS. 5a-c, wherein the plug-in module 5 is inserted into a mounting rack 1, of which only part of the module rail 2 is shown. In FIG. 6a, the adapter 10 is arranged in its starting position. The guide tab 36 pivots the adapter 10 in such a way that the catch element 40 is spaced apart from the toothing 30. The L-limb 22b is inclined relative to the front side of the module rail 2. The adapter 10 can be displaced relative to the circuit board holder 17 in a non-engaged fashion, wherein the guide tab 32 is guided in the guide receptacle 33.

In FIG. 6a, the plug-in module 5 is inserted into the mounting rack 1 such that its connector tab 16 contacts the plug receptacle 20 of the backplane 21.

FIG. 6b shows the position after the spring force of the guide tab 36 is overcome and the adapter 10 is pivoted so far that its L-limb 22b is aligned parallel to the front side of the module rail 2. The catch element 40 engages into the toothing 30 and cooperates with one of the teeth 31. The adapter 10 is now mounted on the module rail by means of the screw 14 (the front thread of which is not illustrated in order to provide a better overview), wherein the screw 14 is screwed into the bore 2a.

FIG. 6c shows the plug-in module 5 that is additionally displaced by two teeth 31 in the inserting direction with reference to the position in FIG. 6b. In this position, the connector tab 16 is completely inserted into the plug receptacle 20 and produces a reliable electric contact. This figure clearly shows that the design of the catch element 40 and the inclined teeth 31 prevent displacement of the plug-in module because the circuit board holder 17 cannot be moved relative to the adapter 10 opposite to the inserting direction.

However, a comparison between FIGS. 6b and 6c shows that the plug-in modules can also be fixed within the mounting rack in different positions due to the standardized permissible tolerances of the plug-in modules 5. In FIG. 6b, a longer circuit board 6 would accordingly be used such that a gap results between the front side of the front plate 7 and the front side of the module rail 2. The inventive mounting device 50 takes into account such a gap in that the toothing 30 of the circuit board holder 17 allows several positions in the longitudinal direction of the plug-in module.

Due to these measures, it is possible to take into account a gap that results between the mounting plane defined by the module rail 2 and the front plate 7 of the plug-in module 5 when the plug-in module 5 completely contacts the plug receptacle 20 of the backplane 21 with its connector tab 16. The plug-in module 5 must be held in this position and, in particular, cannot be moved out of the mounting rack 1. The gap resulting in this end position of the plug-in module 5 is between 0 and approximately 1.6 mm.

The inventive method for mounting a plug-in module 5 in a mounting rack 1 can be elucidated with reference to FIGS. 6a-c. The method comprises the step of inserting the plug-in module 5 into a contact position in the mounting rack 1, namely until the integrated connector tab 16 contacts the plug receptacle 20 of the backplane 21. In another step, the adapter 10 is mounted on the module rail 2 of the mounting rack 1 by means of a mounting element 13 in the form of a screw 14. In another step, the coupling element 23 of the adapter 10 is engaged with the coupling structure 26 of the circuit board holder 17 in such a way that a coupling is produced between the circuit board holder 17 and the adapter 10. In another step, the plug-in module 5 is moved in the inserting direction until the plug-in module 5 is transferred from the contact position into the end position (in the completely inserted state), in which the coupling element 23 is coupled to the coupling structure 26 in such a way that the plug-in module 5 is prevented from moving opposite to the inserting direction.

The sequence of the above-described steps is arbitrary (variable). However, it is possible and preferred that the adapter 10 be connected (fixed on) the module rail 2 of the mounting rack 1 before the plug-in module 5 is inserted into the mounting rack 1. After the adapter 10 is fixed on the module rail 2, the plug-in module 5 can be inserted until the toothed edge 37 of the adapter 10 that forms the coupling element 23 comes in contact and cooperates with the coupling structure 26 in the form of the toothing 30. In this case, the coupling between the adapter 10 and the circuit board holder 17 makes it possible to displace the plug-in module 5 in the inserting direction. However, the plug-in module 5 can only be pulled out of the mounting rack 1 after removing the screw 14 and the adapter 10.

The foregoing description is of an exemplary and preferred embodiments employing at least in part certain teachings of the invention. The invention, as defined by the appended claims, is not limited to the described embodiments. Alterations and modifications to the disclosed embodiments may be made without departing from the invention. The meaning of the terms used in this specification are, unless expressly stated otherwise, intended to have ordinary and customary meaning and are not intended to be limited to the details of the illustrated structures or the disclosed embodiments.

What is claimed is:

1. An electronic plug-in module to be accommodated in a mounting rack, the front region of which features a module rail that extends between the two sidewalls and contains a plurality of bores, comprising:
a circuit board;
a circuit board holder; and
an adapter;
wherein
the adapter comprises a receptacle for a mounting element that can be screwed into a bore in the module rail for mounting the adapter on the module rail;
the circuit board holder is fixed on the circuit board in the front corner region of the circuit board and comprises a coupling structure, with which a corresponding coupling element of the adapter cooperates in order to produce a coupling between the circuit board holder and the adapter; and
the adapter and the circuit board holder are configured for cooperating to hold the plug-in module in its position in the mounting rack when the plug-in module is in an end position in a mounting rack.

2. The plug-in module according to claim 1, wherein the coupling between the circuit board holder and the adapter are configured to allow a relative movement between the adapter and the circuit board holder such that, when it is inserted into a mounting rack, the circuit board of the plug-in module can be moved within a mounting rack in the inserting direction as long as the end position is not reached.

3. The plug-in module according to claim 1, wherein the coupling structure of the circuit board holder comprises a retaining structure and the corresponding coupling element of the adapter comprises a catch element.

4. The plug-in module according to claim 1, wherein the coupling element of the adapter comprises a skid-like coupling element with hooks, and the coupling structure of the circuit board holder comprises a corresponding recess with a toothing.

5. The plug-in module according to claim 1, wherein the adapter comprises a catch tab and the coupling structure of the circuit board holder comprises a plurality of catch elements that are arranged in the mounting rack in the inserting direction of the plug-in module.

6. The plug-in module according to claim 5, wherein the plurality of catch elements are situated on an outer side of the circuit board holder that extends perpendicular to the circuit board.

7. The plug-in module according to claim 1, wherein:
the adapter is angled;
the coupling element is disposed on a limb extending in the longitudinal direction of the circuit board; and
the limb extending perpendicular to the longitudinal direction of the circuit board features the receptacle for the mounting element.

8. The plug-in module according to claim 1, wherein the rear side of the circuit board features an integrated connector tab that can be inserted into a plug receptacle on a backplane of the mounting rack.

9. The plug-in module according to claim 1, wherein the plug-in module further comprises a front plate that is fixed on the circuit board holder.

10. A mounting device for a plug-in module with a circuit board in a mounting rack that includes a module rail on a front side, comprising:
a circuit board holder that can be fixed on a circuit board in the front corner of the circuit board; and
an adapter, the adapter comprising a receptacle for a mounting element in order to mount the adapter on the module rail; wherein
the circuit board holder comprises a coupling structure for coupling with a corresponding coupling element of the adapter in order to produce a coupling between the circuit board holder and the adapter, and
the adapter and the circuit board holder cooperate when the plug-in module is inserted into a mounting rack for holding the plug-in module in its position in the mounting rack.

11. A method for mounting a plug-in module in a mounting rack; the mounting rack comprising a module rail in the front region and a plug receptacle on a backplane; and the plug-in module comprising a circuit board with an integrated connector tab on the rear side, a circuit board holder and an adapter, the circuit board holder being fixed on the circuit board and comprising a coupling structure, and the adapter being comprised of a coupling element for cooperating with the coupling structure of the circuit board holder and a receptacle for a mounting element in order to mount the adapter on the module rail; the method comprising:
inserting the plug-in module into the mounting rack by moving the plug-in module in an inserting direction until the integrated connector tab contacts the plug receptacle of the backplane;
mounting the adapter on the module rail of the mounting rack by means of the mounting element;
engaging the coupling element of the adapter with the coupling structure of the circuit board holder for coupling the circuit board holder and the adapter; and
moving the plug-in module in the inserting direction until the plug-in module has reached an end position and the coupling element is coupled to the coupling structure in such a way that the plug-in module is prevented from moving opposite to the inserting direction.

12. Apparatus comprising:
a mounting rack for receiving electronic plug-in modules, the mounting rack comprising a plug receptacle on a backplane and a module rail on a front side that extends between the two sidewalls of the mounting rack and contains several bores; and
an electronic plug-in module for insertion into the mounting rack in an insertion direction extending from the front side toward the back plane, comprising a circuit board with an integrated connector tab for insertion into the plug receptacle on the rear side, a circuit board holder and an adapter wherein, the adapter comprises a receptacle for a mounting element that can be screwed into a bore in the module rail in order to mount the adapter on the module rail;
the circuit board holder is mounted on the circuit board in the front corner region of the circuit board and comprises a coupling structure for coupling with a corresponding coupling element of the adapter in order to produce a coupling between the circuit board holder and the adapter; the coupling structure being moveable into the mounting rack relative to the coupling element in the inserting direction of the plug-in module; and
the adapter and the circuit board holder cooperate when the plug-in module is in an end position within the mounting rack in such a way that the plug-in module is held in position in the mounting rack.
